(19) United States
(12) Patent Application Publication
(10) Pub. No.: US 2022/0244293 A1
(43) Pub. Date: Aug. 4, 2022

(54) PEAK SELECTION ASSISTANCE FOR RF SPECTRUM ANALYSIS

(71) Applicant: EXFO Inc., Quebec (CA)

(72) Inventors: Dominic LAPIERRE, Rigaud (CA); Martin LEVESQUE, Ile Bizard (CA); Jean-Pierre COUDERT, Montreal (CA)

(21) Appl. No.: 17/648,876

(22) Filed: Jan. 25, 2022

Related U.S. Application Data
(60) Provisional application No. 63/145,825, filed on Feb. 4, 2021.
(60) Provisional application No. 63/263,993, filed on Nov. 12, 2021.

(51) Int. Cl. G01R 13/02

(52) U.S. Cl. CPC G01R 13/0245; G01R 23/18; G01R 13/0281; G01R 13/029

(57) ABSTRACT

In order to improve the analysis of the RF interferences, there is provided a peak selection assistance method for finding a local peak in an RF spectrum trace. The method provides a window on the spectrum trace display, which can be configured and/or moved by a user from user interaction on said user interface. When the window is defined, the method finds the highest peak within the window and optionally adds a marker on it. The method therefore snaps to the highest peak within the window. This improves the way of precisely detecting the maximum amplitude and the center frequency for any local peak on the spectrum.

### TECHNICAL FIELD

The invention relates to RF spectrum analysis and more particularly to tools for analyzing a spectrum to locate RF issues.

### BACKGROUND

RF spectrum analysis is a technology that started in the 1960s. Since then, the performance of the sweep-tune spectrum analyzer was improved and led to the arrival of the real-time spectrum analyzer. However, the way the user operates a spectrum analyzer has not evolved much. There remains a need to improve the user experience, by considering the end-user point of view and looking into ways to make it easier to analyze and troubleshoot RF issues. FIG. 1 shows a spectrum trace displayed on the user interface of an RF spectrum analyzer.

Traditionally, in a RF spectrum analyzer interface, users can display and use markers. The user may place such a marker on the spectrum trace and can move it manually along the frequency axis. Once placed at a chosen frequency, the marker reports the amplitude (usually in dBm) at this frequency using the trace data.

Markers are typically used by the user to obtain the amplitude and frequency data for one or more peaks in the spectrum. Peaks may represent RF interferences that the user is trying to locate to address in the field. Manually placing a marker in the general area of one peak is relatively easy for the user but it is not precise due to the limited resolution of the display and the sensitivity of the touch sensors (if screen gestures are used). Zooming the display can improve precision but requires tedious back and forth between spectrum spans. In general, having the marker fall exactly on the maximum of the chosen peak using a manual entry method requires substantial skill and trial-and-error effort. In general, a manual entry method does not yield a precise selection of the chosen peak in a convenient manner.

Automated ways of placing these markers are available on the market. The maximum peak of the trace is typically easy to identify and mark using a simple software solution. It requires searching through the trace data to find the point of highest amplitude. This becomes the maximum peak. This is usually referred to as the “Go-To-Peak” functionality. Upon selection of this tool, the software identifies the maximum value of the trace data and displays a marker aligned on the maximum peak, with its associated amplitude and frequency data, for the user. For example, FIG. 2 shows the trace of FIG. 1 with a marker M1 on the highest peak (highest amplitude). In this example, the following metrics are given for that marker: ID: M1, Frequency: 4.986963 GHz, Amplitude: −55.79 dBm.

In some prior art solutions, another type of automated marker placement or localization is available, namely the “Next/Previous Peak” or peak identification feature. It locates and places a marker on the peak which is located to the immediate right or left of the currently-selected peak or cursor location. Typically, the algorithms of the prior art solutions work well for obvious peaks but have limited success in more complex situations. Indeed, except for the most obvious traces, it is difficult to implement a computer algorithm that will find the next important peak without being sidetracked by the noise on the trace or the shape of the trace. For certain signals, the user must press “Next/Previous Peak” several times to get to the peak of interest, while for other signals, the algorithm may altogether skip the desired peak, forcing the user to resort to the manual entry method. FIG. 3 shows such a spectrum trace where such prior art algorithms would not allow to find and analyze the Peak 2 because it barely stands out from a wideband signal of interest, i.e., a LTE signal in this specific case. Similarly, such prior art algorithms would not allow to find and analyze Peak 3 because although it does stand out from the local wideband signal, its amplitude level is below the overall signal average level.

Furthermore, the highest peak is never a perfect Dirac delta function, i.e., it has a given width. The peak is drawn on the user interface with many pixels. If the solution simply attempts to find a point of amplitude that is lower than the maximum peak itself, it will simply find the adjacent pixels to the maximum peak itself and not a separate and distinct peak. The algorithm has to keep searching until the amplitude rises again. But it cannot stop searching as soon as the amplitude rises, it has to continue searching until the amplitude stops rising. Then it identifies a next peak. If the trace is noisy and has many ups and downs, this can cause multiple identifications of relatively unimportant peaks. Many adjacent peaks can be found and identified rendering the feature useless as it can't determine the relative importance of the peaks.

Moreover, the spectrum trace usually includes more data points (amplitude values) than can be displayed. Therefore, it is possible that the actual maximum for a secondary peak is not even apparent on the spectrum as currently displayed and therefore cannot be found by manual entry methods.

The performance of the peak identification feature of prior art spectrum analyzers is therefore unsatisfactory and there remains a need for an improved peak selection method for RF spectrum analyzers to assist users in selecting peaks more precisely.

### SUMMARY

In order to improve the analysis of the RF interferences, there is provided a peak selection assistance method for selecting a local peak in an RF spectrum trace. The method provides a window on the spectrum trace display, which can be configured and/or moved by a user from user interaction on said user interface. When the window is defined, the method finds the highest peak within the window and optionally adds a marker on it. The method therefore snaps to the highest peak within the window. This improves the way of precisely detecting the maximum amplitude and the center frequency for almost any local peak on the spectrum.

In one embodiment, the window is first displayed at any position along the frequency axis and can be dragged along the frequency axis by user interaction. When the window is released by the user, the method identifies the highest peak within the frequency window as released and adds a marker on it.

According to one broad aspect of the present invention, there is provided a method for identifying a maximum value in a section of a trace displayed to a user on a RF spectrum analyzer interface. The method comprises providing a display of said trace using trace data including frequency and amplitude components on said RF spectrum analyzer interface; providing a movable window with a first edge and a second edge and a width between said first edge and said second edge, adapted to be displaced by user interaction along a frequency axis of said trace; receiving an indication that said movable window is at a chosen position along said frequency axis; selecting a subset of said trace data using said first edge and said second edge at said chosen position along said frequency axis; determining a maximum of said amplitude within said subset of trace data to obtain said maximum value; determining a corresponding frequency value for said maximum value; providing information about said maximum value of said amplitude and said corresponding frequency value.

In accordance with one aspect, there is provided a method for assisting a user in selecting a local peak in a spectrum trace obtained using a RF spectrum analyzer. The method comprises:
providing a user interface on said RF spectrum analyzer, comprising a display of said spectrum trace that is generated from trace data representing RF signal amplitude values as a function of frequency and obtained using the RF spectrum analyzer;
from user interaction on said user interface, defining a window along a frequency axis of said spectrum trace, the window comprising a lower edge and an upper edge visually represented on said display;
selecting a subset of said trace data using said lower edge and said upper edge of said window as defined along said frequency axis;
determining a maximum of said amplitude values within said subset of said trace data;
determining a corresponding frequency value for the maximum amplitude value; and
outputting said maximum amplitude value and said corresponding frequency value to a user.

A marker may optionally be displayed on the display at the corresponding frequency value.

In accordance with another aspect, there is provided a non-transitory computer-readable storage medium comprising instructions that, when executed, cause a processor to perform the steps of:
providing a user interface on said RF spectrum analyzer, comprising a display of said spectrum trace that is generated from trace data representing RF signal amplitude values as a function of frequency and obtained using the RF spectrum analyzer;
from user interaction on said user interface, defining a window along a frequency axis of said spectrum trace, the window comprising a lower edge and an upper edge visually represented on said display;
selecting a subset of said trace data using said first edge and said second edge of said window as defined along said frequency axis;
determining a maximum of said amplitude values within said subset of said trace data;
determining a corresponding frequency value for the maximum amplitude value; and
outputting said maximum amplitude value and said corresponding frequency value to a user.

In accordance with yet another aspect, there is provided an RF spectrum analyzer device comprising:
an IQ data acquisition device and a digital signal processing module for measuring trace data representing RF signal amplitude values as a function of frequency;
a processing unit receiving the trace data and configured for:
   providing a user interface comprising a display of a spectrum trace that is generated from trace data;
   from user interaction on said user interface, defining a window along a frequency axis of said spectrum trace, the window comprising a lower edge and an upper edge visually represented on said display;
   selecting a subset of said trace data using said first edge and said second edge of said window as defined along said frequency axis;
   determining a maximum of said amplitude values within said subset of said trace data;
   determining a corresponding frequency value for the maximum amplitude value; and
   outputting said maximum amplitude value and said corresponding frequency value to a user.

### BRIEF DESCRIPTION OF THE DRAWINGS

Having thus generally described the nature of the invention, reference will now be made to the accompanying drawings, showing by way of illustration example embodiments thereof and in which:

FIG. 1 shows an example of a spectrum trace displayed on a graphical user interface of an RF spectrum analyzer;

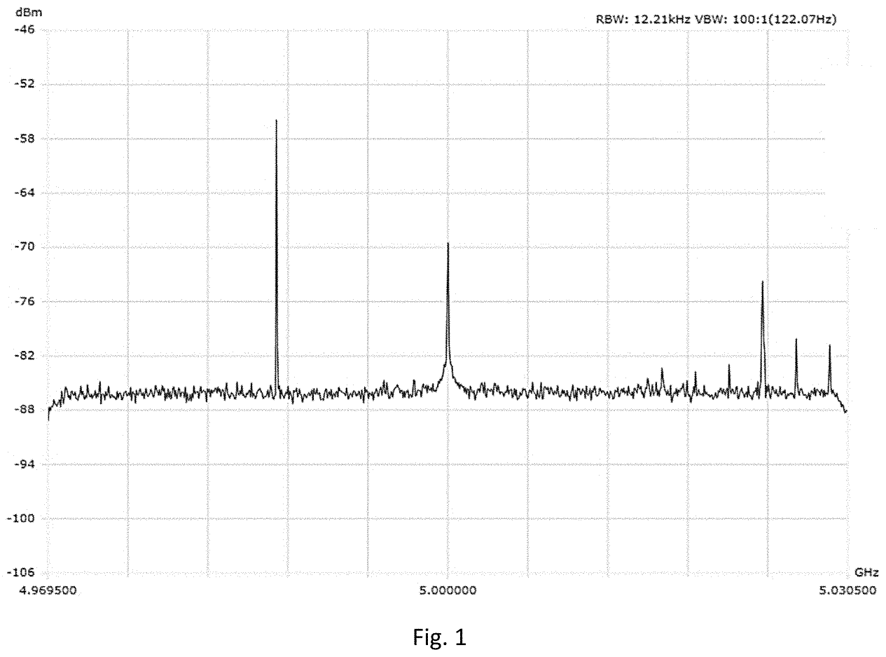

FIG. 2 shows the spectrum trace of FIG. 1 in which a marker M1 is added on the maximum peak;

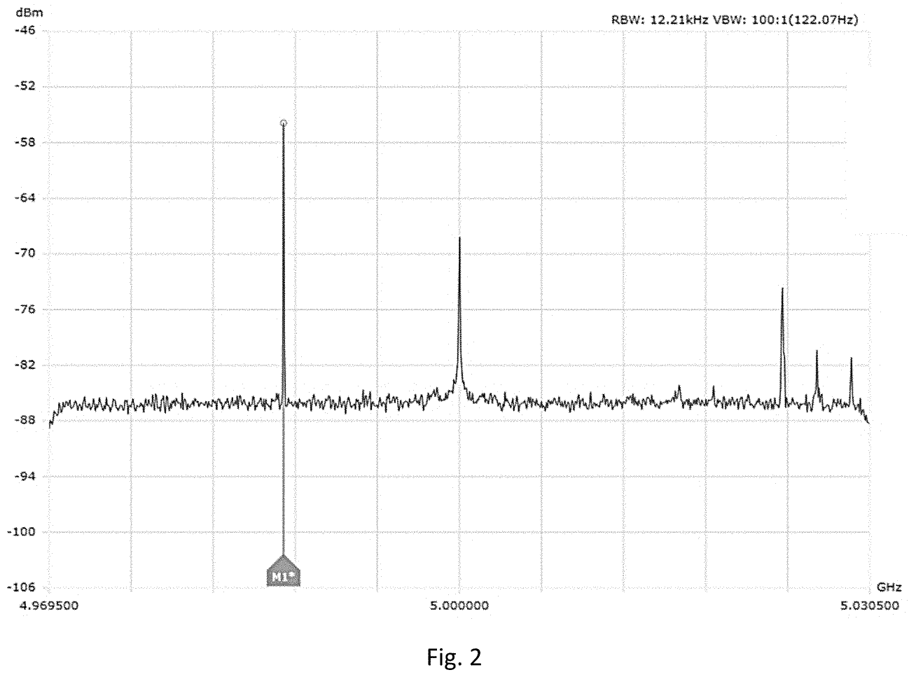

FIG. 3 shows another example of an RF spectrum trace in which some peaks cannot be easily identified by prior art algorithms;

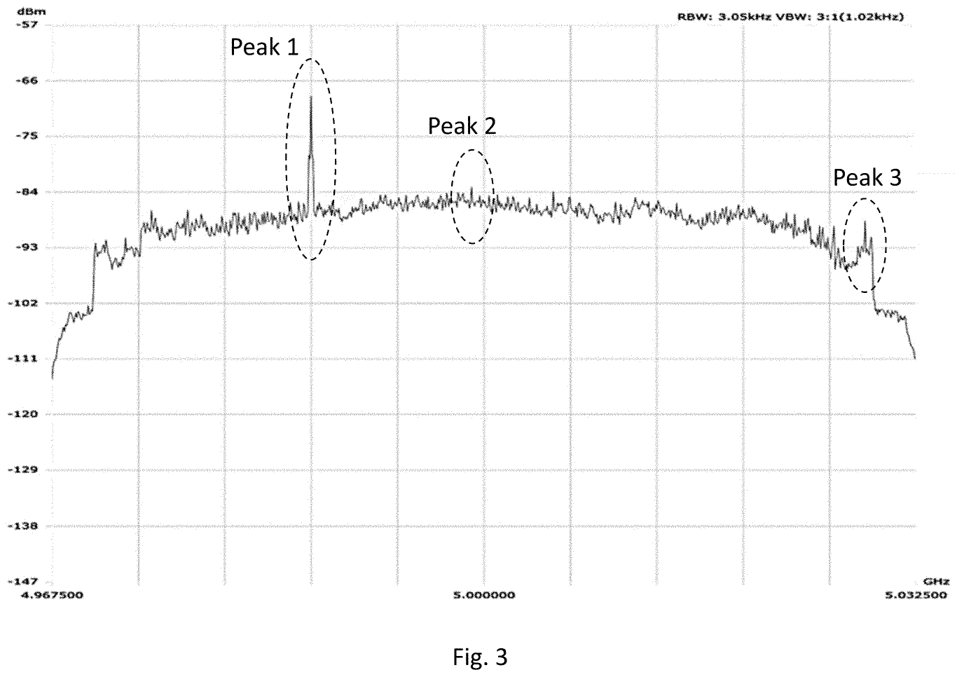

FIG. 4 shows an example of a graphical user interface of an RF spectrum analyzer which comprises a display of a spectrum trace, along with a persistence spectrum view, in accordance with one embodiment;

FIG. 5 shows the spectrum trace display of FIG. 1 in which a window is displayed as part of a peak selection assistance method, in accordance with one embodiment;

FIG. 6 shows the spectrum trace display of FIG. 1 in which a marker M2 is positioned over a secondary peak once the window is positioned thereover, in accordance with one embodiment;

FIG. 7 shows the spectrum trace display of FIG. 1 in which the marker M2 remains in position over the secondary peak after the window is removed, in accordance with one embodiment;

FIG. 8 shows the spectrum trace display of FIG. 1 in which a marker M1 is positioned over another secondary peak once the window is positioned thereover, in accordance with one embodiment in which the peak is barely located within the window, on a right side thereof;

FIG. 9 shows the spectrum trace display of FIG. 1 in which the marker M1 is positioned over the secondary peak once the window is positioned thereover, in accordance with one embodiment in which the peak is barely located within the window, on a left side thereof;

FIG. 10 shows another example of an RF spectrum trace in which the primary and a secondary peak are closely located;

FIG. 11 shows the spectrum trace display of FIG. 10 in which a window allows to select the secondary peak as part of the peak selection assistance method;

FIG. 12 shows another example of a graphical user interface of an RF spectrum analyzer which comprises a display of a spectrum trace along with a spectrogram view, in accordance with one embodiment; and

FIG. 13 is a block diagram illustrating an example architecture of an RF spectrum analyzer device, in accordance with one embodiment.

It will be noted that throughout the drawings, like features are identified by like reference numerals. In the following description, similar features in the drawings have been given similar reference numerals and, to not unduly encumber the figures, some elements may not be indicated on some figures if they were already identified in a preceding figure. It should be understood herein that elements of the drawings are not necessarily depicted to scale, since emphasis is placed upon clearly illustrating the elements and structures of the present embodiments. Some mechanical or other physical components may also be omitted in order to not encumber the figures.

The following description is provided to gain a comprehensive understanding of the methods, apparatus and/or systems described herein. Various changes, modifications, and equivalents of the methods, apparatuses and/or systems described herein will suggest themselves to those of ordinary skill in the art. Description of well-known functions and structures may be omitted to enhance clarity and conciseness.

Although some features may be described with respect to individual exemplary embodiments, aspects need not be limited thereto such that features from one or more exemplary embodiments may be combinable with other features from one or more exemplary embodiments.

### DETAILED DESCRIPTION

The present method and system for peak selection assistance may be used to improve the analysis of the RF interferences by assisting the user to select and analyze a local peak in the RF spectrum. This method facilitates taking measurements with an RF spectrum analyzer.

In order to improve the analysis of the RF interferences, there is provided a peak selection assistance method for selecting a local peak in an RF spectrum trace. This feature is referred to herein as the “snap-to-peak” features.

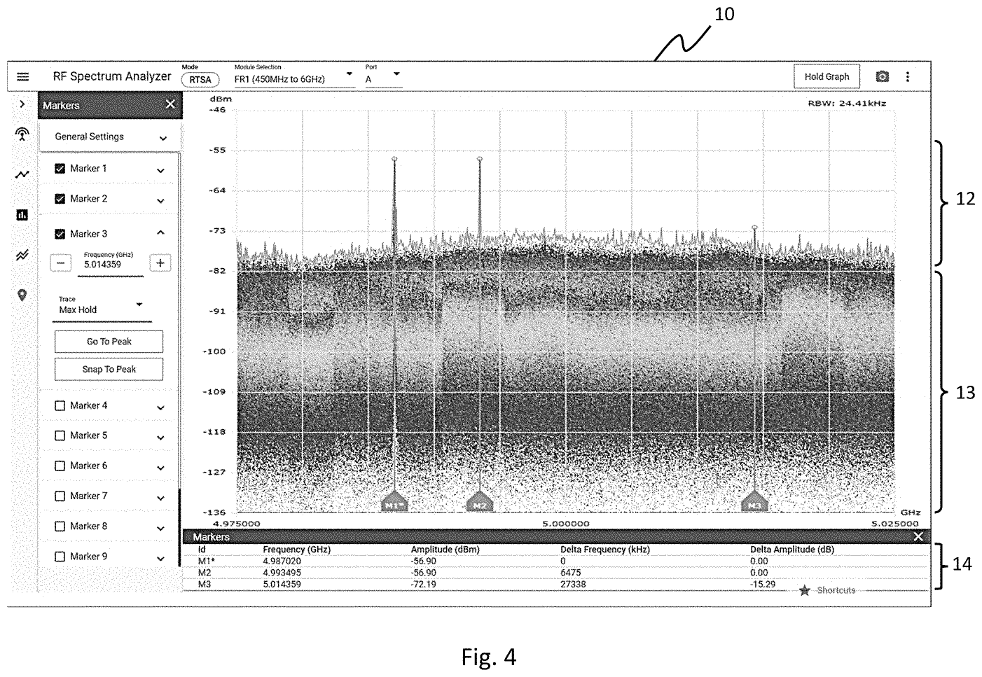

FIG. 4 shows an example of a user interface 10 that is provided on the display screen of the RF spectrum analyzer, in accordance with one embodiment. The user interface 10 comprises a display 12 of a spectrum trace that is generated from trace data representing RF signal amplitude values as a function of frequency as measured using the RF spectrum analyzer. In the embodiment of FIG. 4, in addition to the display 12, the user interface 10 further comprises a persistence spectrum view 13 used to illustrate real-time RF spectrum acquisition results. As known in the art, in such persistence view the signal density is encoded in a time-frequency view using colors (although FIG. 4 is only provided herein in gray tones), in which the signal density is defined as the percentage of the time where a signal is present at a given frequency. The longer a particular frequency persists in a signal as the signal evolves, the higher its time percentage and thus the brighter or “hotter” its color in the display.

It is noted that, due to the limited resolution of the display screen, the spectrum trace as displayed may have a reduced resolution compared to the whole trace data as measured by the RF spectrum analyzer.

Here, the user interface 10 also shows markers M1, M2, M3 positioned on the highest peak (located at marker position M1), as well as secondary peaks (located at marker positions M2 and M3) and selected using the peak selection assistance method. The user interface 10 further shows a peak analysis display area 14 which is used to output the maximum amplitude value and the frequency value corresponding to each marker M1, M2, M3 and therefore to each peak found using the peak selection assistance method.

The first embodiment is now herein described with reference to FIGS. 4 to 11.

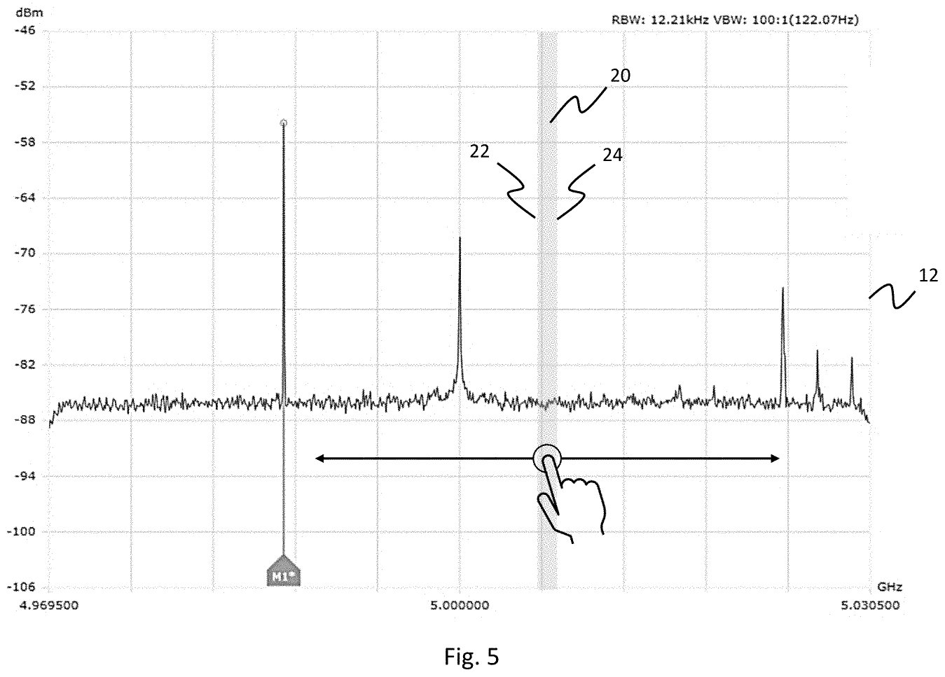

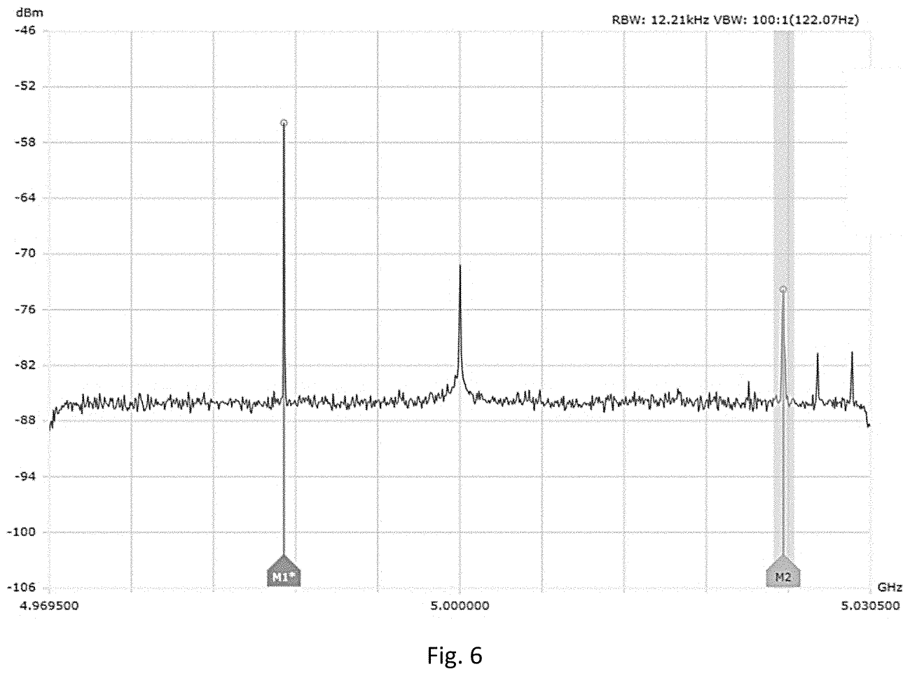

FIGS. 5 and 6 show a spectrum trace display 12 as may be displayed as part of the user interface 10 of FIG. 4 during use of the peak selection assistance feature, in accordance with one embodiment. The peak selection assistance method provides a window 20 displayed over the spectrum trace display, which can be configured by a user from user interaction on the user interface. Marker M1 is positioned on the highest peak (highest amplitude) over the whole span of the trace data. Marker M2 is the one that is snapped on to the selected local peak as the window is moved during active searching for a new peak.

As shown in FIG. 5, the window may be shown as a colored area (different from the graph background) over the spectrum trace display 12 between a first edge 22 and a second edge 24 of the window 20, respectively corresponding to a lower and an upper frequency value along the frequency axis (and thereafter respectively referred to as the lower edge 22 and the upper edge 24). Limits of the contrasted area visually represent the lower edge 22 and the upper edge 24. This contrasted area helps the user place the window to encompass a section of interest along the frequency axis, over which to find a local peak.

The window 20 may be initially displayed at any arbitrary position along the frequency axis, such as, for example, the center of the spectrum trace display 12 and may have an initial predetermined width between the lower edge and the upper edge, as per software configuration.

For example, the initial width of the window 20 may be defined as proportion (e.g., a percentage) of the full bandwidth of the displayed spectrum trace, or as a predetermined frequency bandwidth. For example, the window width may be between 1 and 15% of the full bandwidth. In an example embodiment, the default window width is 2.5% of the span of the displayed spectrum trace. This width of the window can be made predefined by software configuration or be made customizable by the user via settings. In an example embodiment, the width of the window is configurable between 2 and 5%. A user may input a preferred width by entering a percentage value or a frequency value in a settings field. In other embodiment, the window width may be defined by the user interaction on the user interface using, e.g., a two-finger gesture on a touchscreen interface, the space between the two fingers indicating the desired width of the window.

From user interaction on the user interface, a position of the window may be moved along the frequency axis. In this example embodiment, the window 20 can be dragged by the user using a pointing device and released at the desired position, i.e., over the peak to be analyzed. For example, the window 20 may be dragged using finger gestures on a touch screen or using a mouse click hold, depending on the interface used. When the user is satisfied with the position of the window, he/she releases the pointing device by, for example, lifting the finger from the touchscreen or releasing the mouse button. Releasing the window 20 herein constitutes an indication that that the window 20 is at a chosen position along the frequency axis.

As illustrated in FIG. 6, when the window is released, peak analysis begins. The software finds and selects the highest peak within the window 20 and may add a marker on the user interface at the peak position.

It is noted that, due to the limited resolution of the display screen, the spectrum trace as displayed may have a lower resolution compared to the whole trace data as measured by the RF spectrum analyzer. Various decimation methods as known in the art may be used to obtain the displayed trace with such a lower resolution. For example, in one embodiment, the spectrum trace as displayed may include 1024 pixels whereas the actual trace data includes 128 k FFTs. The trace has 128 times more data points and thus provides a precision that is increased by a factor of 128. In order to precisely find the local peak within the window 20, the software searches for the maximum amplitude value using the trace data instead of the displayed spectrum trace.

The software selects a subset of the trace data using the lower edge and the upper edge of the window as defined along said frequency axis. In other words, it looks only into the trace data for which the frequency values are between the frequencies corresponding to the lower and the upper edge. It then finds the maximum of the amplitude values within this subset of the trace data, as well as the corresponding frequency value. These values are then output to the user on the user interface, e.g., by being displayed in the peak analysis display area 14.

The method therefore searches for the precise peak within the window as defined by the user, within the trace data that contains more precise data. The actual frequency of the peak from the trace data can be identified without being limited by display resolution. This improves the way of precisely detecting the maximum amplitude and the center frequency for any peak within the RF spectrum.

The software finds the maximum amplitude value in the window as selected by the user, and not over the whole bandwidth, hence covering the region of interest as indicated by the user. The method thereby snaps to the highest peak within the window. This method allows to detect the maximum amplitude and the center frequency for almost any local peak on the spectrum.

Of course, there may be some exception cases such as, e.g., if more than two peaks are close enough to be encompassed together within the frequency span of the window. The central peak would then be difficult to isolate but selecting a smaller window may help to avoid such issue.

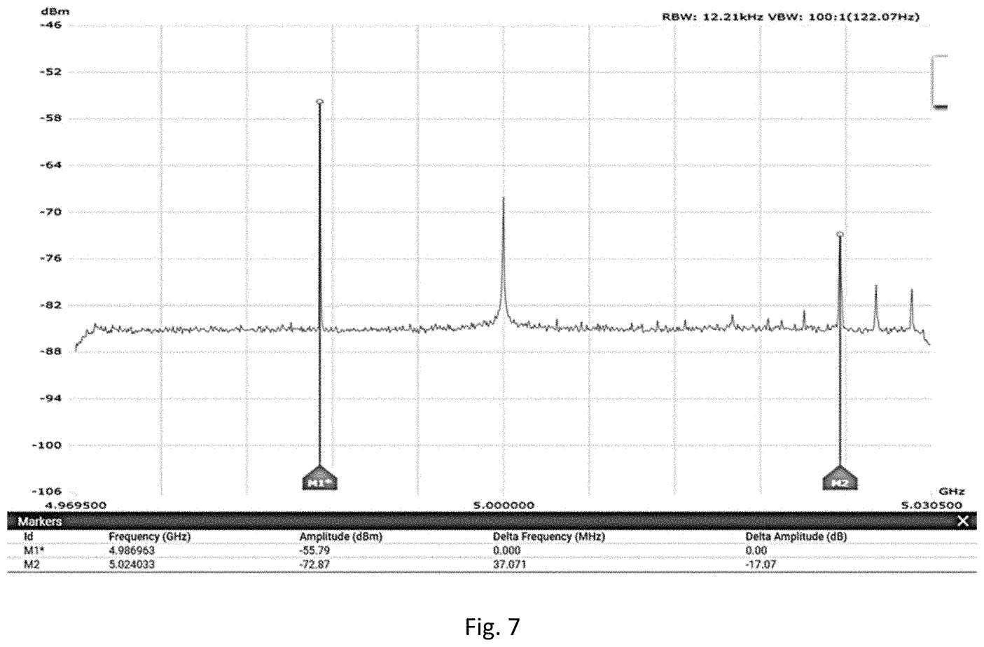

As shown in FIG. 7, after completion of the peak selection assistance process, the window may disappear from the display and the marker M2 may remain in position on the local peak as selected with the help of the peak selection assistance feature, while its corresponding amplitude and frequency values remain displayed in the peak analysis display area 14.

The peak selection assistance feature may then be used again on the same spectrum trace in order to position as many other markers as necessary. A marker can then be positioned on each peak considered of importance by the user and its corresponding metrics be displayed in the peak analysis display area 14 which outputs a table showing the metrics associated with each marker.

When looking for harmonics, it is often desirable to determine the difference in amplitude and frequency (delta) between markers. Because the peak selection assistance feature provides a more precise selection of a peak in any region of the spectrum, the delta calculation between two peaks selected using this method is more precise. Such delta values may further be displayed in the peak analysis display area 14. The user interface may further allow to sort the marked peaks by amplitude level to create a priority list of the interferences that have the biggest impact.

Some other optional characteristics of the peak selection assistance feature may further assist the user.

In some embodiments, when the user moves the window 20 along the frequency axis, the software constantly identifies the highest peak within the window and updates the marker in real-time. This gives precious feedback to the user when selecting a peak. It is noted that the processing speed of the system may not be sufficient to make real-time calculations of the high peak based on the whole data set of the trace data. For this reason, the method may determine a preliminary maximum amplitude value and corresponding frequency value based on the lower-resolution spectrum trace being displayed. This preliminary calculation based on the lower-resolution data set may allow better real-time feedback to the user.

Accordingly, while the window is being moved or reconfigured, the following steps are continuously repeated. The software selects preliminary subset of the lower-resolution spectrum trace using the lower edge and the upper edge of the window as currently defined. In other words, it looks only into the lower-resolution spectrum trace data points for which the frequency values are between the frequencies corresponding to the lower and the upper edge. It then finds the maximum of the amplitude values within this subset, as well as the corresponding frequency value. These preliminary values are then output to the user on the user interface, e.g., by being displayed in the peak analysis display area 14 or anywhere else. The search for the highest peak within the window may be repeated multiple times per second and displayed to the user to give immediate feedback while the window is being moved.

Furthermore, once the position of the window is defined (e.g., the window is released), the software may optionally continuously update the maximum amplitude value associated with the marker as new measurement data comes in. To do so, as the software continuously receives and displays new trace data measured by the RF spectrum analyzer, it continuously repeats the steps of determining the amplitude value (updated amplitude value) at the frequency value of the marker; and outputting the updated amplitude value, e.g., in the peak analysis display area 14. According, the marker frequency remains fixed as previously determined and only the amplitude value is updated.

In other embodiments, the marker position may also be updated as new measurement data comes in. To do so, as the software continuously receives and displays new trace data measured by the RF spectrum analyzer, it continuously repeats the steps of selecting a subset on the new trace data using the lower and upper edges of the window, determining a maximum amplitude value and a corresponding frequency value within the subset, and outputting these values.

FIG. 7 shows an example of a spectrum trace with a marker M1 positioned on the highest peak (highest amplitude) over the whole span of the trace data and a marker M2 positioned on a secondary peak selected using the peak selection assistance feature. In this example, the following metrics are found for the markers:
ID: M1, Frequency: 4.986963 GHz, Amplitude: −55.79 dBm
ID: M2, Frequency: 5.024033 GHz, Amplitude: −72.87 dBm

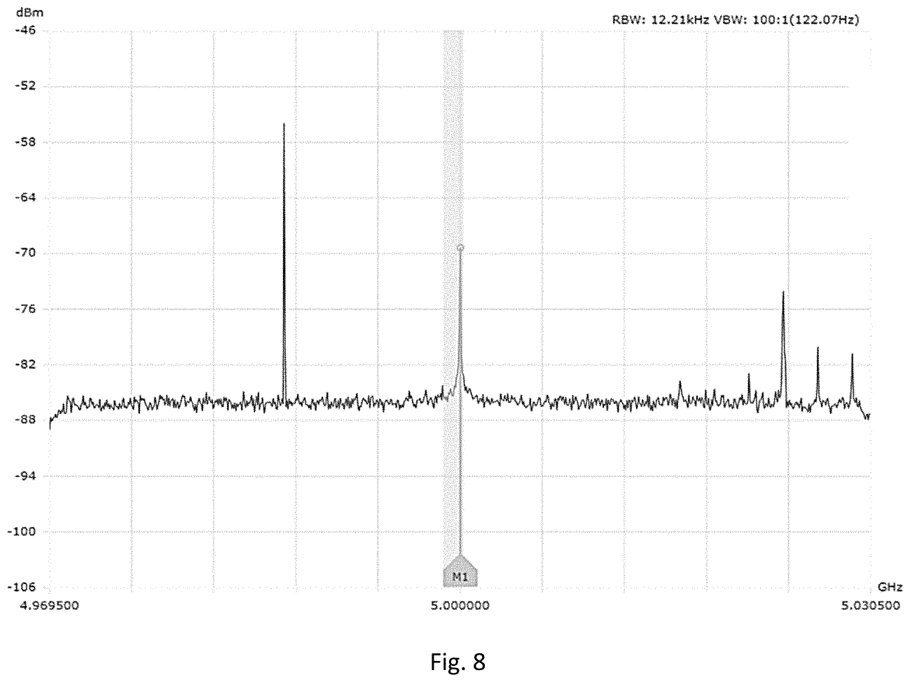

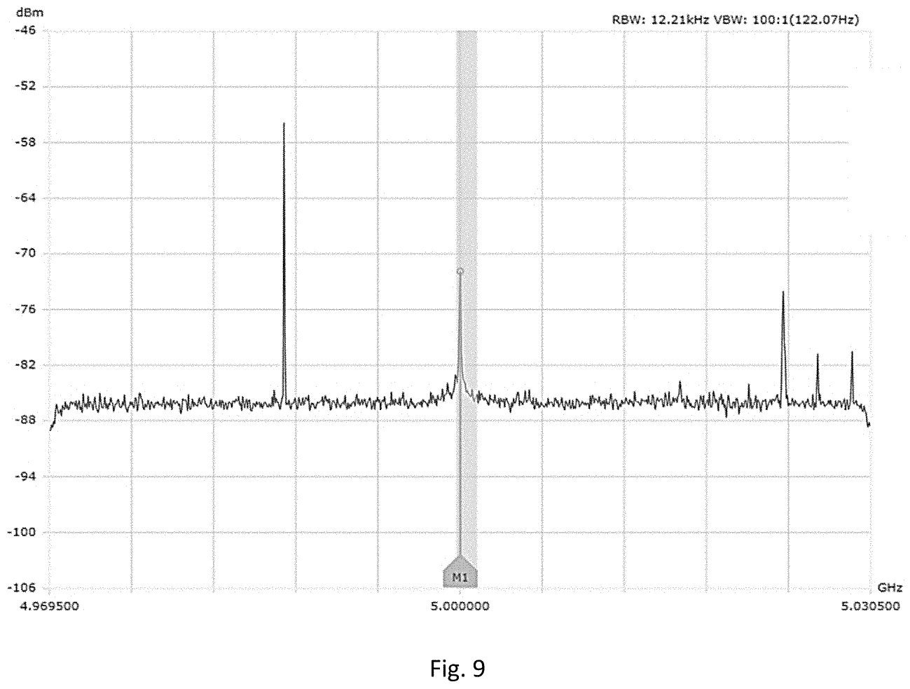

FIGS. 8 and 9 illustrates how the precision on the marker positioning can be improved by the peak selection assistance feature. Using a pointing device with the user interface, the user may drag the window so encompass the peak to be selected without having to center the window on the peak, as long as the peak lies anywhere between the lower and upper edges of the window, even if barely located within the window. The wider the window, the less the required positioning precision.

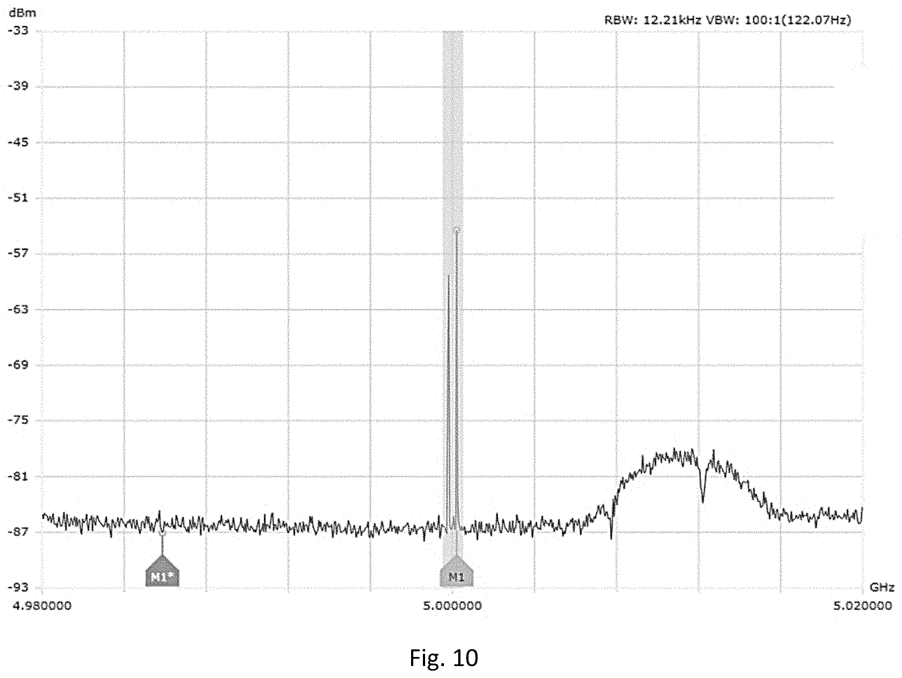

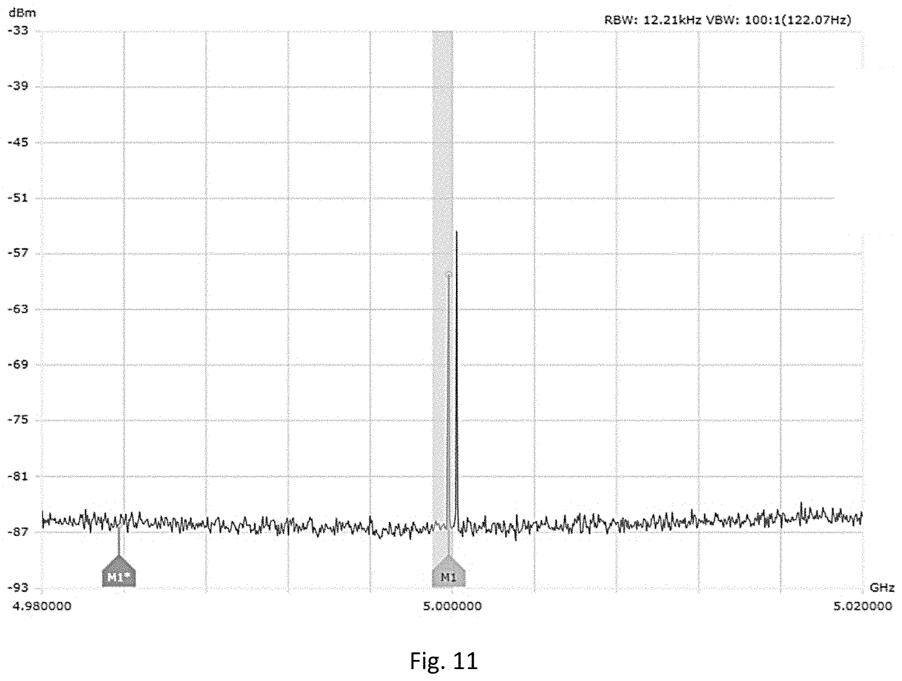

FIGS. 10 and 11 illustrates how the peak selection assistance feature can be used to assist in selecting a secondary peak that is located very close to the highest peak (M1) or any other peak. As shown in FIG. 10, if the window is positioned so as to encompass both peaks, the marker will be snapped on to the highest one only. However, as shown in FIG. 11, slightly moving the window so that one edge falls between the two peaks will allow to snap on to the secondary peak. The user may slowly drag the window out of the highest one of the two peaks while the software updates the marker in real-time and, once the user is satisfied with the location of the marker, he/she may release the pointing device so as to place the marker on the secondary peak.

The embodiments described herein with reference to FIGS. 4 to 11 are implemented so that, when the peak selection assistance feature is selected, a window appears on the user interface, which the user may drag and release along the frequency axis. It is noted that other possible user interactions may be envisaged. For example, in another embodiment, the edges and variable width of the window may be defined using a different user interaction in which the user draws the window on the display. For example, the window may be drawn using a two-finger gesture in which the user slides two fingers away or toward one another on the touch screen. Removing the fingers from the screen constitutes an indication that the window 20 is at a chosen position along the frequency axis. The position of each finger along the frequency axis just before they are removed, indicates the desired position of the window edges (the space between the two fingers thereby indicating the desired width of the window). In another example, the window may be drawn by the user using a click, drag and release gesture on screen, the click indicating the desired position of the first edge and the release indicating the desired position of the second edge of the window.

Furthermore, once the window is positioned, the user interface may optionally allow the user to move a position of any one edge of the window along the frequency axis, e.g., by a drag and drop gesture on the edge.

It is noted that a similar method may be used to identify and mark edges of a plateau in the RF spectrum. Similarly, a ‘snap-to-edge’ feature may be used to position a window along the frequency axis, where to look for the edge of a plateau instead of a peak. An additional step of using a contrast-enhancing filter and edge detector (or any other combination of filters) can be used to first highlight the sides of the plateau. It can then look for the bottom and top peaks at each edge of the plateau.

It will be understood that state of the art RF spectrum signal processing can be used along with the peak selection assistance tool in order to improve detection of RF interferers hidden into noise. For example, filtering methods such as that described in U.S. Pat. No. 11,121,785 to Levesque may be applied to perform a localized peak auto-detection that is able to discern a peak hidden in noise. Such filtering method may be used to better position the marker on a peak within the defined window. It may also be used for moving peaks. For example, after positioning the window and selecting a peak, the algorithm may continue to track the peak position within the window, providing the capability to report statistics such as maximum peak displacement.

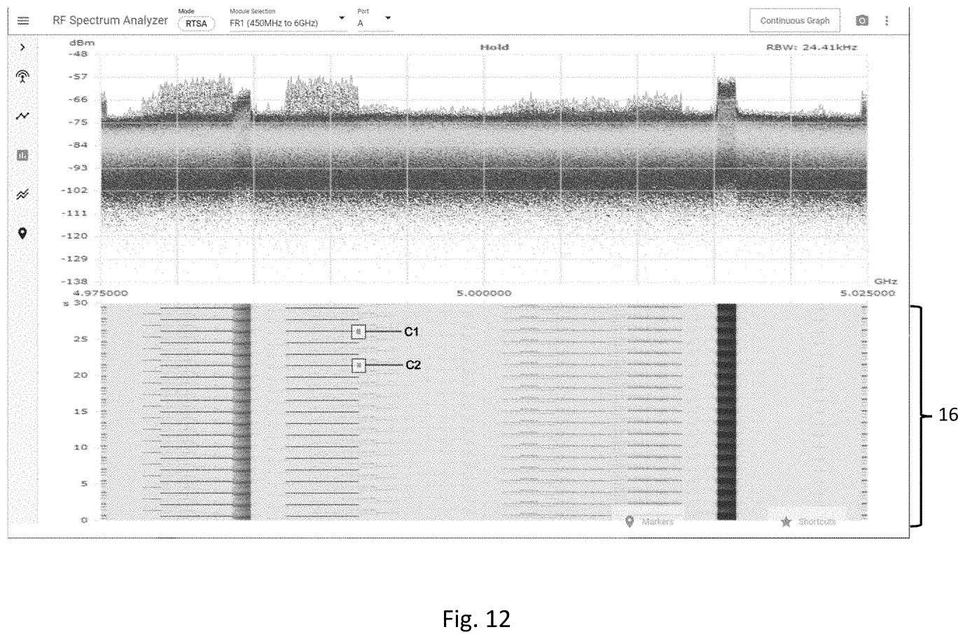

Referring to FIG. 12, the user interface may further include a spectrogram view 16. A spectrogram is a graphical representation of the signals across a frequency range, generally color-coded to indicate signal amplitude or strength, displayed over time. The snap-to-peak and snap-to-edge features may also be applied to the spectrogram view. After a pre-processing step to increase the contrast, a line detection algorithm can be used over the selection window to determine the frequency of the detected line. To provide even more measurement capabilities, the peak selection assistance feature can be used over a frozen spectrogram, i.e., a snapshot of the spectrogram at a given time. The window described hereinabove may then be replaced by a square (see C1 and C2) that can be moved over the spectrogram view. In addition to assisting selection in the frequency domain (either peak or edge), the algorithm can perform the same processing over the time domain, thus providing precise measurement of signal duration, interval between signal, etc.

Example of RF Spectrum Analyzer Device Architecture

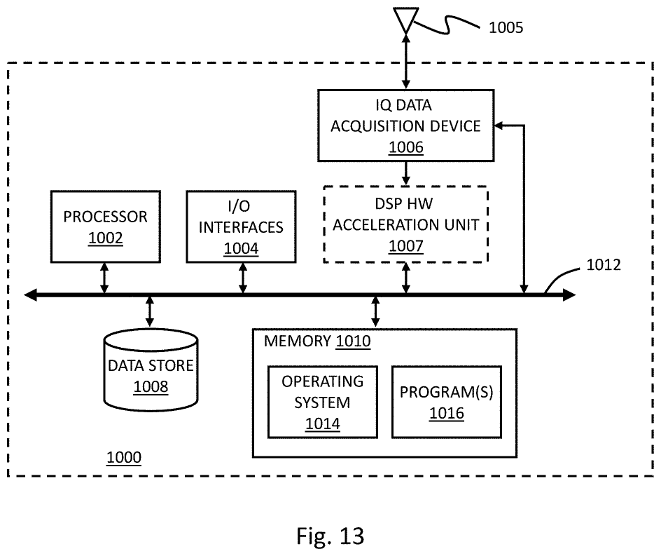

FIG. 13 is a block diagram of an RF spectrum analyzer device 1000 which may comprise the peak selection assistance feature described herein. The RF spectrum analyzer device 1000 may comprise a digital device that, in terms of hardware architecture, generally includes a processor 1002, input/output (I/O) interfaces 1004, an RF antenna 1005, an IQ data acquisition device 1006, an optional DSP hardware acceleration unit 1007, a data store 1008, a memory 1010. It should be appreciated by those of ordinary skill in the art that FIG. 13 depicts the RF spectrum analyzer device 1000 in a simplified manner, and a practical embodiment may include additional components and suitably configured processing logic to support known or conventional operating features that are not described in detail herein. A local interface 1012 interconnects the major components. The local interface 1012 can be, for example, but not limited to, one or more buses or other wired or wireless connections, as is known in the art. The local interface 1012 can have additional elements, which are omitted for simplicity, such as controllers, buffers (caches), drivers, repeaters, and receivers, among many others, to enable communications. Further, the local interface 1012 may include address, control, and/or data connections to enable appropriate communications among the aforementioned components.

The processor 1002 is a hardware device for executing software instructions. The processor 1002 may comprise one or more processors, including central processing units (CPU), auxiliary processor(s) such as a graphics processing unit, or generally any device for executing software instructions. When the RF spectrum analyzer device 1000 is in operation, the processor 1002 is configured to execute software stored within the memory 1010, to communicate data to and from the memory 1010, and to generally control operations of the RF spectrum analyzer device 1000 pursuant to the software instructions. The I/O interfaces 1004 can be used to receive user input from and/or for providing system output. User input can be provided via, for example, a keypad, a touch screen, a scroll ball, a scroll bar, buttons, barcode scanner, and the like. System output can be provided via a display device such as a liquid crystal display (LCD), touch screen, and the like, via one or more LEDs or a set of LEDs, or via one or more buzzer or beepers, etc. The I/O interfaces 1004 can be used to display a graphical user interface (GUI) that enables a user to interact with the RF spectrum analyzer device 1000 and/or output at least one of the values derived by the RF spectrum analyzer.

The signal is received by the RF antenna 1005 and the IQ data acquisition device 1006 is used to tune the signal and bring it to a proper level. It may include an RF front-end including, e.g., low-noise amplification, filtering, conditioning, etc., in hardware circuitry. The IQ data acquisition device 1006 further comprises an analog to digital converter to sample the resulting signal.

Data is then be processed using digital signal processing such as Fast Fourier Transforms (FFT), filtering, decimation, computing power density array, etc., to produce trace data representing RF signal amplitude values as a function of frequency. A digital signal processing module may be implemented in hardware (DSP hardware acceleration 1007), in software executed by the central processing unit, or a combination of both. If included, the optional DSP hardware acceleration unit 1007 may comprise dedicated hardware and/or FPGA circuitry to execute some DSP computations.

The data store 1008 may be used to store data, such as RF spectrum traces and measurement data files. The data store 1008 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 1008 may incorporate electronic, magnetic, optical, and/or other types of storage media.

The memory 1010 may include any of volatile memory elements (e.g., random access memory (RAM, such as DRAM, SRAM, SDRAM, etc.)), nonvolatile memory elements (e.g., ROM, hard drive, etc.), and combinations thereof. Moreover, the memory 1010 may incorporate electronic, magnetic, optical, and/or other types of storage media. Note that the memory 1010 may have a distributed architecture, where various components are situated remotely from one another, but can be accessed by the processor 1002. The software in memory 1010 can include one or more computer programs, each of which includes an ordered listing of executable instructions for implementing logical functions. In the example of FIG. 13, the software in the memory 1010 includes a suitable operating system (O/S) 1014 and computer programs 1016. The operating system 1014 essentially controls the execution of other computer programs and provides scheduling, input-output control, file and data management, memory management, and communication control and related services. The program(s) 1016 may include various applications, add-ons, etc. configured to provide end-user functionality with the RF spectrum analyzer device 1000. For example, example programs 1016 may include a web browser to connect with a server for transferring measurement data files, a dedicated RF spectrum analyzer application configured to control RF signal acquisitions by the RF spectrum acquisition device 1018, set acquisition parameters, analyze spectrum traces obtained by the RF spectrum acquisition device 1018 and display the user interface related to the RF spectrum analyzer device 1000. For example, the dedicated RF spectrum application may embody the user interface described herein.

It is noted that, in some embodiments, the I/O interfaces 1004 may be provided via a physically distinct mobile device (not shown), such as a handheld computer, a smartphone, a tablet computer, a laptop computer, a wearable computer or the like, e.g., communicatively coupled to the RF spectrum analyzer device 1000 via a radio antenna. In such cases, at least some of the programs 1016 may be located in a memory of such a mobile device, for execution by a processor of the physically distinct device. The mobile may then also include a radio and be used to transfer measurement data files toward a remote test application residing, e.g., on a server.

It should be noted that the RF spectrum analyzer device shown in FIG. 13 is meant as an illustrative example only. Numerous types of computer systems are available and can be used to implement the RF spectrum analyzer device.

The embodiments described above are intended to be exemplary only. The scope of the invention is therefore intended to be limited solely by the appended claims.

1. A method for assisting a user in selecting a local peak in a spectrum trace obtained using a RF spectrum analyzer, the method comprising:
providing a user interface on said RF spectrum analyzer, comprising a display of said spectrum trace that is generated from trace data representing RF signal amplitude values as a function of frequency and obtained using the RF spectrum analyzer;
from user interaction on said user interface, defining a window along a frequency axis of said spectrum trace, the window comprising a lower edge and an upper edge visually represented on said display;
selecting a subset of said trace data using said lower edge and said upper edge of said window as defined along said frequency axis;
determining a maximum of said amplitude values within said subset of said trace data;
determining a corresponding frequency value for the maximum amplitude value; and
outputting said maximum amplitude value and said corresponding frequency value.

2. The method as claimed in claim 1, further comprising:
displaying a marker on said display at said corresponding frequency value.

3. The method as claimed in claim 1, wherein said step of defining a window further comprises:
displaying a window at an arbitrary position along the frequency axis, said window having a predetermined width between said first edge and said second edge; and
from user interaction on said user interface, moving a position of the window along said frequency axis.

4. The method as claimed in claim 3, wherein said width of said window is fixed.

5. The method as claimed in claim 3, wherein said width of said window is adjustable and wherein said step of defining a window further comprises:
from user interaction on said user interface, moving a position of at least one edge of the window along said frequency axis.

6. The method as claimed in claim 1, wherein said width of said window is variable and wherein said step of defining a window further comprises:
defining positions of the lower edge and the upper edge of the window from a user interaction on said user interface in which the user draws the window on the display.

7. The method as claimed in claim 1, wherein said steps of selecting a subset, determining a maximum of said amplitude values, determining a corresponding frequency value and outputting said maximum amplitude value are conducted upon an indication that said window is at a chosen position along said frequency axis.

8. The method as claimed in claim 1, wherein said spectrum trace is displayed with lower resolution than said trace data.

9. The method as claimed in claim 8, wherein, while said window is being moved or reconfigured, continuously repeating the steps of:
selecting a preliminary subset of said lower-resolution spectrum trace being displayed, using said lower edge and said upper edge of said window as currently defined;
determining a preliminary maximum amplitude value within said preliminary subset of said spectrum trace;
determining a corresponding frequency value for said preliminary maximum amplitude value; and
outputting said preliminary maximum amplitude value and said corresponding frequency value to a user.

10. The method as claimed in claim 1, wherein said user interface continuously receives and displays new trace data measured by the RF spectrum analyzer, and after the window is defined, continuously repeating steps of:
determining an updated amplitude value at said frequency value; and
outputting said updated amplitude value.

11. A non-transitory computer-readable storage medium comprising instructions that, when executed, cause a processor to perform the steps of:
providing a user interface on said RF spectrum analyzer, comprising a display of said spectrum trace that is generated from trace data representing RF signal amplitude values as a function of frequency and obtained using the RF spectrum analyzer;
from user interaction on said user interface, defining a window along a frequency axis of said spectrum trace, the window comprising a lower edge and an upper edge visually represented on said display;
selecting a subset of said trace data using said first edge and said second edge of said window as defined along said frequency axis;
determining a maximum of said amplitude values within said subset of said trace data;
determining a corresponding frequency value for the maximum amplitude value; and
outputting said maximum amplitude value and said corresponding frequency value to a user.

12. The non-transitory computer-readable storage medium as claimed in claim 11, comprising further instructions that, when executed, cause a processor to perform the steps of:
displaying a marker on said display at said corresponding frequency value.

13. The non-transitory computer-readable storage medium as claimed in claim 11, wherein said spectrum trace is displayed with lower resolution than said trace data.

14. The non-transitory computer-readable storage medium as claimed in claim 13, wherein, while said window is being moved or reconfigured, the processor continuously repeats the steps of:
selecting a preliminary subset of said lower-resolution spectrum trace being displayed, using said first edge and said second edge of said window as currently defined;
determining a preliminary maximum amplitude value within said preliminary subset of said spectrum trace;
determining a corresponding frequency value for said preliminary maximum amplitude value; and
outputting said preliminary maximum amplitude value and said corresponding frequency value to a user.

15. An RF spectrum analyzer device comprising:
an IQ data acquisition device and a digital signal processing module for measuring trace data representing RF signal amplitude values as a function of frequency;
a processing unit receiving the trace data and configured for:
providing a user interface comprising a display of a spectrum trace that is generated from trace data;
from user interaction on said user interface, defining a window along a frequency axis of said spectrum trace, the window comprising a lower edge and an upper edge visually represented on said display;
selecting a subset of said trace data using said first edge and said second edge of said window as defined along said frequency axis;
determining a maximum of said amplitude values within said subset of said trace data;
determining a corresponding frequency value for the maximum amplitude value; and
outputting said maximum amplitude value and said corresponding frequency value to a user.

16. The RF spectrum analyzer device as claimed in claim 15, wherein said processing unit is further configured for displaying a marker on said display at said corresponding frequency value.

17. The RF spectrum analyzer device as claimed in claim 11, wherein said spectrum trace is displayed with lower resolution than said trace data.

18. The RF spectrum analyzer device as claimed in claim 13, wherein said processing unit is further configured for, while said window is being moved or reconfigured, continuously repeating the steps of:
selecting a preliminary subset of said lower-resolution spectrum trace being displayed, using said first edge and said second edge of said window as currently defined;
determining a preliminary maximum amplitude value within said preliminary subset of said spectrum trace;
determining a corresponding frequency value for said preliminary maximum amplitude value;
outputting said preliminary maximum amplitude value and said corresponding frequency value to a user.

19. The RF spectrum analyzer device as claimed in claim 13, wherein the digital signal processing unit comprises a DSP hardware acceleration unit.

20. A method for identifying a maximum value in a section of a trace displayed to a user on a RF spectrum analyzer interface, comprising:
providing a display of said trace using trace data including frequency and amplitude components on said RF spectrum analyzer interface;
providing a movable window with a first edge and a second edge and a width between said first edge and said second edge, adapted to be displaced by user interaction along a frequency axis of said trace;
receiving an indication that said movable window is at a chosen position along said frequency axis;
selecting a subset of said trace data using said first edge and said second edge at said chosen position along said frequency axis;
determining a maximum of said amplitude within said subset of trace data to obtain said maximum value;
determining a corresponding frequency value for said maximum value;
providing information about said maximum value of said amplitude and said corresponding frequency value.
